(19) United States
(12) Patent Application Publication
(10) Pub. No.: US 2016/0076890 A1
(43) Pub. Date: Mar. 17, 2016

(54) VIBRATION UNIT AND ANGULAR VELOCITY SENSOR MODULE

(71) Applicant: SAMSUNG ELECTRO-MECHANICS CO., LTD., Suwon-Si (KR)

(72) Inventor: Yu Heon YI, Suwon-Si (KR)

(73) Assignee: SAMSUNG ELECTRO-MECHANICS CO., LTD., Suwon-Si (KR)

(21) Appl. No.: 14/658,450

(22) Filed: Mar. 16, 2015

(30) Foreign Application Priority Data
Sep. 16, 2014 (KR) 10-2014-0122536

(51) Int. Cl. G01C 19/5621; H03H 9/21

(52) U.S. Cl. CPC G01C 19/5621; H03H 9/21

(57) ABSTRACT

A vibration unit includes: a first vibration member configured to be extended from a body member and vibrated on a first plane based on a first driving signal; and a second vibration member configured to be extended from the body member, disposed to be non-parallel with respect to the first vibration member, and vibrated on the first plane based on a second driving signal.

### CROSS-REFERENCE TO RELATED APPLICATION

This application claims the priority and benefit of Korean Patent Application No. 10-2014-0122536 filed on Sep. 16, 2014, with the Korean Intellectual Property Office, the disclosure of which is incorporated herein by reference.

### BACKGROUND

The present inventive concept relates to a vibration unit and an angular velocity sensor module configured to sense angular velocities on two or more axes.

An angular velocity sensor is configured to measure angular velocity generated at the time of rotary motion. As an example thereof, a tuning fork angular velocity sensor measures angular velocity using Coriolis force.

Such a tuning fork angular velocity sensor measures angular velocities using an oscillator extended in a single axial direction. Since an angular velocity sensor having the above-mentioned structure has an angular velocity sensing range limited by the direction of extension of the oscillator, it may be difficult to sense various types of angular velocity.

In order to solve the above-mentioned issue, an angular velocity sensor having a plurality of oscillators is proposed. However, since the size of such an angular velocity sensor having the above-mentioned structure may not be easily reduced, it may be difficult to use such an angular velocity sensor in a portable terminal.

For reference, Patent Documents 1 and 2 are provided as a related art associated with the present inventive concept.

### RELATED ART DOCUMENT

(Patent Document 1) JP2006-275881 A

(Patent Document 2) US2011-0174073 A1

### SUMMARY

An aspect of the present inventive concept may provide a vibration unit and an angular velocity sensor module, a size of which may be easily reduced while being able to sense various types of angular velocity.

According to an aspect of the present inventive concept, a vibration unit may sense angular velocities on two or more axes using a plurality of vibration members disposed to be non-parallel with respect to one another.

### BRIEF DESCRIPTION OF DRAWINGS

The above and other aspects, features and other advantages of the present inventive concept will be more clearly understood from the following detailed description taken in conjunction with the accompanying drawings, in which:

FIG. 1 is a perspective view of an angular velocity sensor module according to an exemplary embodiment in the present inventive concept;

FIG. 2 is a view illustrating a circuit configuration of the angular velocity sensor illustrated in FIG. 1;

FIG. 3 is an enlarged perspective view of a vibration unit illustrated in FIG. 1;

FIG. 4 is a view illustrating a driving mode of a vibration unit illustrated in FIG. 2;

FIG. 5 is a view illustrating a first sensing mode of the vibration unit illustrated in FIG. 2;

FIG. 6 is a view illustrating a second sensing mode of the vibration unit illustrated in FIG. 2;

FIG. 7 is a perspective view of an angular velocity sensor module according to another exemplary embodiment in the present inventive concept;

FIG. 8 is an enlarged perspective view of a vibration unit illustrated in FIG. 7;

FIG. 9 is a view illustrating a driving mode of a vibration unit illustrated in FIG. 8;

FIG. 10 is a view illustrating a first sensing mode of the vibration unit illustrated in FIG. 8;

FIG. 11 is a view illustrating a second sensing mode of the vibration unit illustrated in FIG. 8;

FIG. 12 is a perspective view of an angular velocity sensor module according to another exemplary embodiment in the present inventive concept;

FIG. 13 is an enlarged perspective view of a vibration unit illustrated in FIG. 12;

FIG. 14 is a view illustrating a driving mode of a vibration unit illustrated in FIG. 13;

FIG. 15 is a view illustrating a first sensing mode of the vibration unit illustrated in FIG. 13; and

FIG. 16 is a view illustrating a second sensing mode of the vibration unit illustrated in FIG. 13.

### DETAILED DESCRIPTION

Exemplary embodiments of the present inventive concept will now be described in detail with reference to the accompanying drawings.

The inventive concept may, however, be exemplified in many different forms and should not be construed as being limited to the specific embodiments set forth herein. Rather, these embodiments are provided so that this disclosure will be thorough and complete, and will fully convey the scope of the inventive concept to those skilled in the art.

In the drawings, the shapes and dimensions of elements may be exaggerated for clarity, and the same reference numerals will be used throughout to designate the same or like elements.

As used herein, in the present inventive concept, when an element is referred to as being “connected to,” it may be “directly connected to” and may also be “indirectly connected to” while having intervening elements therebetween. In addition, it will be further understood that the terms “include” and/or “have” when used in the present inventive concept, specify the presence of elements, but do not preclude the presence or addition of one or more other elements, unless otherwise indicated.

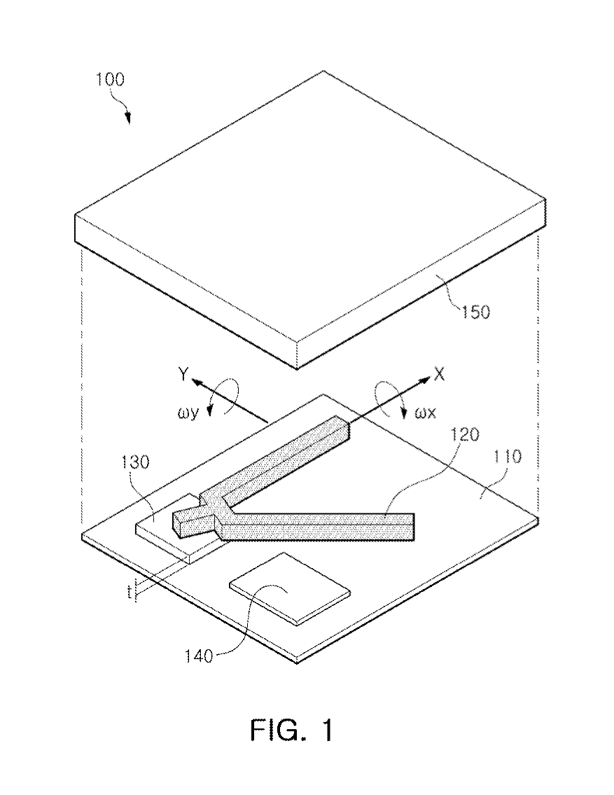

For reference, hereinafter, a first plane refers to a plane in parallel with respect to X-Y plane based on FIG. 1, angular velocity ωx refers to an angular velocity generated by rotary motion based on an X axis illustrated in FIG. 1, and angular velocity ωy refers to an angular velocity generated by rotary motion based on an Y axis illustrated in FIG. 1. In addition, a direction of Coriolis force applied to a vibration member according to an exemplary embodiment in the present inventive concept is based on the northern hemisphere.

Referring to FIG. 1, an angular velocity sensor module according to an exemplary embodiment in the present inventive concept will be described.

An angular velocity sensor module 100 may include a vibration unit 120. Further, the angular velocity sensor module 100 may further include a control unit 140. In addition, the angular velocity sensor module 100 may further include a substrate member 110, a pedestal member 130, and a cover member 150.

Hereinafter, the above-mentioned components will be described based on an order of reference numerals.

The substrate member 110 may be a printed circuit board (PCB) on which a circuit pattern is formed. For example, the substrate member 110 may have one or more circuit patterns connecting the vibration unit 120 and the control unit 140 to each other formed therein. The substrate member 110 may be a portion of a portable terminal in which the vibration unit 120 is mounted. For example, the substrate member 110 may be a main circuit substrate of the portable terminal.

The vibration unit 120 may be mounted on the substrate member 110. For example, the vibration unit 120 may be disposed to be vibrated on a first plane (X-Y plane based on FIG. 1) parallel with respect to the substrate member 110.

The pedestal member 130 may be disposed between the substrate member 110 and the vibration unit 120. The pedestal member 130 may have a predetermined thickness. For example, the pedestal member 130 may have a thickness t larger than a vibration displacement of the vibration unit 120. The pedestal member 130 formed as described above may prevent collision between the substrate member 110 and the vibration unit 120.

The control unit 140 may be configured to control driving of the vibration unit 120. For example, the control unit 140 may transmit a driving signal so that the vibration unit 120 is vibrated on the first plane. The control unit 140 may be configured to sense an electrical signal of the vibration unit 120. For example, the control unit 140 may sense the electrical signal of the vibration unit 120 caused by rotary motion based on an X axis or a Y axis. In addition, the control unit 140 may be configured to recognize a direction of the rotary motion based on the electrical signal.

The cover member 150 may be configured to be coupled to the substrate member 110. For example, the cover member 150 may be configured to cover an open portion of the substrate member 110. The cover member 150 formed as described above may prevent damage to the vibration member 120 due to external impacts. The cover member 150 may be configured to block electromagnetic waves. For example, the cover member 150 may be configured to protect the vibration unit 120 and the control unit 140 from harmful electromagnetic waves generated externally.

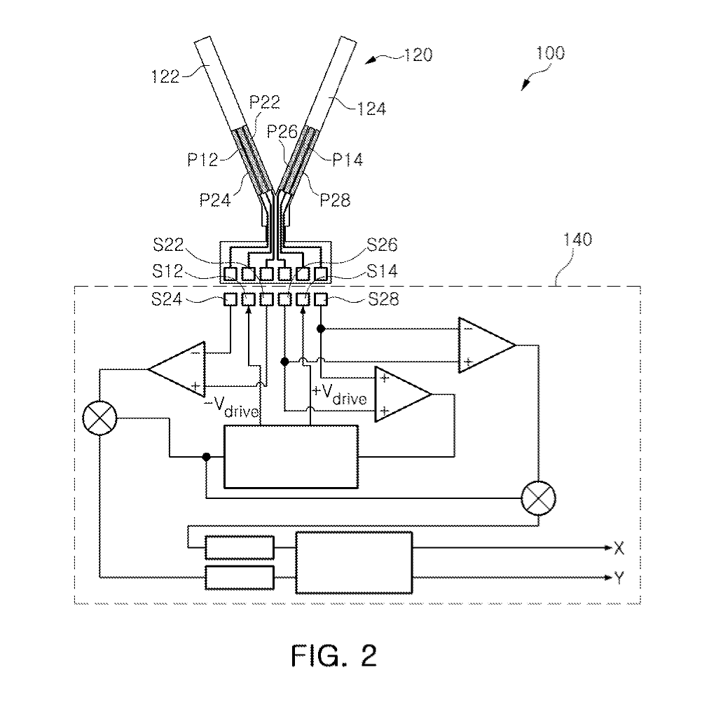

Referring to FIG. 2, the vibration unit of the angular velocity sensor module according to the present exemplary embodiment will be described.

The vibration unit 120 may include a plurality of vibration members 122 and 124. For example, the vibration unit 120 may include a first vibration member 122 and a second vibration member 124. The vibration unit 120 may include a plurality of piezoelectric elements P12, P14, P22, P24, P26, and P28. For example, the first vibration member 122 may have a first piezoelectric element P12 and second piezoelectric elements P22 and P24 formed therein, and the second vibration member 124 may have a first piezoelectric element P14 and second piezoelectric elements P26 and P28 formed therein.

The first piezoelectric elements P12 and P14 may be configured to drive the first vibration member 122 and the second vibration member 124. For example, the first piezoelectric element P12 may provide driving force so that the first vibration member 122 is repeatedly rotated in clockwise and counterclockwise directions on the first plane (X-Y plane based on FIG. 1), and the first piezoelectric element P14 may provide driving force so that the second vibration member 124 is repeatedly rotated in clockwise and counterclockwise directions on the first plane (X-Y plane based on FIG. 1). The first piezoelectric element P12 and the first piezoelectric element P14 may provide driving force so that the first vibration member 122 and the second vibration member 124 are vibrated in directions opposing each other. For example, the first piezoelectric element P12 may sequentially perform rotary motion of the first vibration member 122 in the clockwise direction and the counterclockwise direction, and the first piezoelectric element P14 may sequentially perform rotary motion of the second vibration member 124 in the counterclockwise direction and the clockwise direction. The first piezoelectric elements P12 and P14 configured as described above may be formed to be elongated along center lines of the vibration members 122 and 124.

The second piezoelectric elements P22, P24, P26, and P28 may be configured to convert deformation (or vibrations) of the first vibration member 122 and the second vibration member 124 into an electrical signal. For example, the second piezoelectric elements P22 and P24 may be configured to convert the deformation of the first vibration member 122 occurring in a direction perpendicular to the first plane into the electrical signal, and the second piezoelectric elements P26 and P28 may be configured to convert the deformation of the second vibration member 124 occurring in a direction perpendicular to the first plane into the electrical signal. The second piezoelectric elements P22, P24, and the second piezoelectric elements P26, P28 configured as described above may be formed on both sides of the vibration members 122 and 124, respectively.

The vibration unit 120 may be connected to the control unit 140. For example, the piezoelectric elements P12, P14, P22, P24, P26, and P28 of the vibration unit 120 may be connected to terminals S12, S14, S22, S24, S26, and S28 of the control unit 140, respectively. The control unit 140 may include an input terminal and an output terminal. For example, the terminals S12 and S14 may be used as the output terminals and the terminals S22, S24, S26, and S28 may be used as the input terminals. The output terminals S12 and S14 may transmit a driving signal. For example, the output terminals S12 and S14 may be configured to transmit a signal necessary to drive the first piezoelectric elements P12 and P14. The input terminals S22, S24, S26, and S28 may receive a sensing signal. For example, the input terminals S22, S24, S26, and S28 may be configured to sense the electrical signal transmitted from the second piezoelectric elements P22, P24, P26, and P28.

The vibration unit 120 may include a circuit amplifying or modulating a driving signal and a sensing signal. For example, the vibration unit 120 may include an amplification circuit, a modulation circuit, an operation circuit, and a comparison circuit.

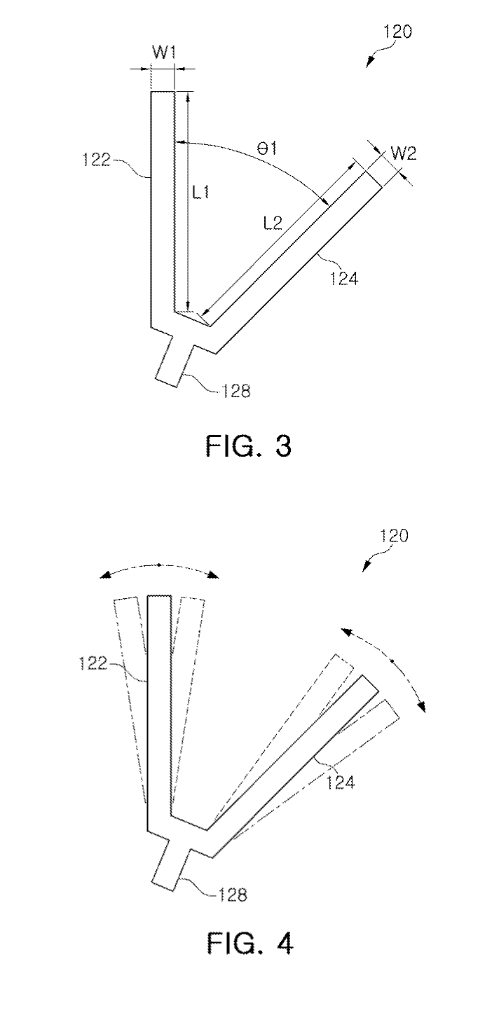

Referring to FIG. 3, a form of the vibration unit will be described.

The vibration unit 120 may include the plurality of vibration members 122 and 124. Further, the vibration unit 120 may include a body member 128.

The body member 128 may be configured to be fixed to the substrate member 110. For example, the body member 128 may be a portion of the vibration unit 120 in which occurrence of deformation is absent. The body member 128 may be provided with a plurality of terminals connected to the control unit 140. For example, the body member 128 may be provided with connection terminals for electrically connecting the piezoelectric elements P12, P14, P22, P24, P26, and P28 of the vibration unit 120 and the terminals S12, S14, S22, S24, S26, and S28 of the control unit 140 to each other, respectively.

The vibration members 122 and 124 may be formed to be extended from the body member 128. For example, the first vibration member 122 may be formed to be elongated from one side of the body member 128 to one direction of the body member 128, and the second vibration member 124 may be formed to be elongated from one side of the body member 128 to another direction of the body member 128. The first vibration member 122 and the second vibration member 124 may be disposed to form a predetermined angle θ1. For example, a first angle θ1 formed by the first vibration member 122 and the second vibration member 124 based on the body member 128 may be selected from a range of 10 to 80 degrees. However, the size of the first angle θ1 is not limited to the above-mentioned range. For example, the first angle θ1 may be arbitrarily selected from an acute angle range or a right angle.

The first vibration member 122 and the second vibration member 124 may have the same shape as each other. For example, a length L1 of the first vibration member 122 and a length L2 of the second vibration member 124 may be the same as each other. Further, a width w1 of the first vibration member 122 and a width w2 of the second vibration member 124 may be the same as each other. The first vibration member 122 and the second vibration member 124 may be symmetrical to each other. For example, the first vibration member 122 and the second vibration member 124 may be disposed to be symmetrical to each other based on the body member 128.

The vibration member 120 configured as described above may be advantageous for sensing various angular velocities.

The vibration unit 120 may have a plurality of modes. For example, the vibration unit 120 may include a vibration mode, a first sensing mode, and a second sensing mode. Hereinafter, operation modes of the vibration unit 120 based on the respective modes will be described.

Referring to FIG. 4, a driving mode of the vibration unit will be described.

The vibration unit 120 may be operated in the driving mode. For example, the vibration unit 120 may be operated in the driving mode in a state in which angular velocity ωx of the X axis and angular velocity ωy of the Y axis are absent.

The driving mode of the vibration unit 120 may be operated so that the first vibration member 122 and the second vibration member 124 are vibrated in a direction parallel with respect to the first plane. For example, the first vibration member 122 may be driven to be rotated in a clockwise direction by a primary driving signal, and may be driven to be rotated in a counterclockwise direction by a secondary driving signal. Similarly, the second vibration member 124 may be driven to be rotated in the counterclockwise direction by a primary driving signal, and may be driven to be rotated in the clockwise direction by a secondary driving signal.

In the driving mode, rotary motions of the vibration members 122 and 124 by driving signal may only occur. Therefore, transmission of the electrical signal caused by deformation in the vibration members 122 and 124 may not occur in the driving mode.

In a case in which a shaking occurs in the above-mentioned driving mode, the vibration unit 120 may be operated in the first sensing mode or the second sensing mode based on a direction of the shaking.

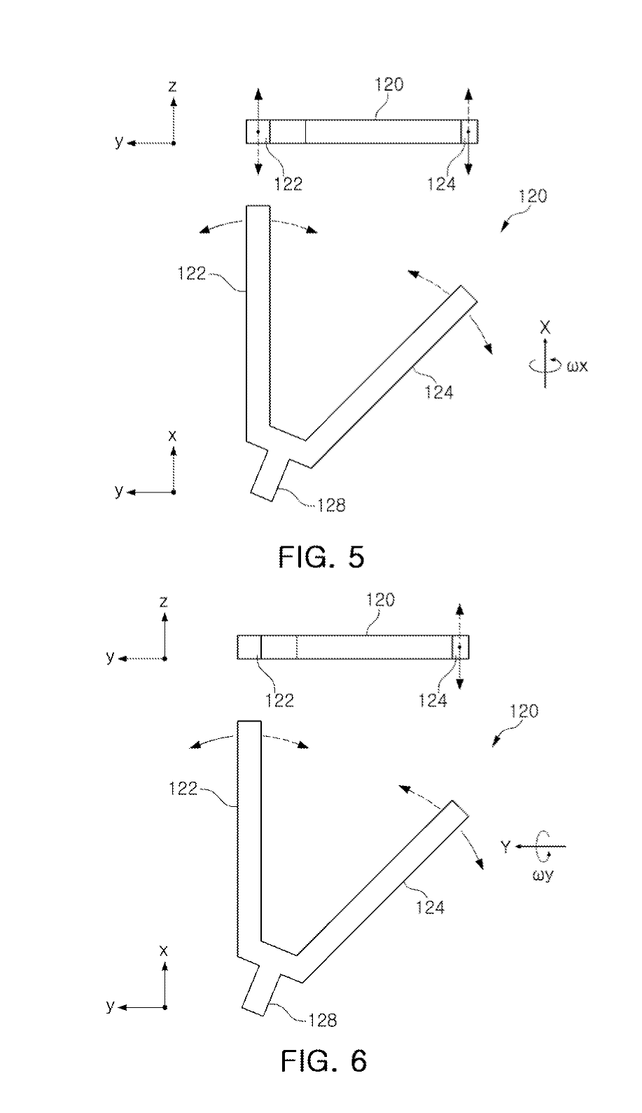

Referring to FIG. 5, a first sensing mode of the vibration unit will be described.

In a case in which angular velocity ωx in the X axis is generated in the driving mode, the vibration unit 120 may be operated in the first sensing mode as illustrated in FIG. 5. For example, the first vibration member 122 of the vibration unit 120 may be vibrated in a direction of a +Z axis together with rotation of the first vibration member 122 in the clockwise direction, and may be vibrated in a direction of a −Z axis together with rotation of the first vibration member 122 in the counterclockwise direction. Similarly, the second vibration member 124 of the vibration unit 120 may be vibrated in the direction of the −Z axis together with rotation of the second vibration member 124 in the counterclockwise direction, and may be vibrated in the direction of the +Z axis together with rotation of the second vibration member 124 in the clockwise direction.

The vibration unit 120 may transmit an electrical signal in the first sensing mode. For example, the vibration members 122 and 124 of the vibration unit 120 may transmit the electrical signal while being vibrated in the direction of the Z axis as described above. The electrical signal transmitted from the vibration unit 120 may be sensed by the control unit 140. The control unit 140 may determine magnitudes and directions of angular velocities using magnitudes and deviations of the electrical signal transmitted from the first vibration member 122 and the second vibration member 124.

Referring to FIG. 6, a second sensing mode of the vibration unit will be described.

In a case in which angular velocity ωy in the Y axis is generated in the driving mode, the vibration unit 120 may be operated in the second sensing mode as illustrated in FIG. 6. For example, the second vibration member 124 of the vibration unit 120 may be vibrated in the direction of the −Z axis together with rotation of the vibration member 124 in the counterclockwise direction, and may be vibrated in the direction of the +Z axis together with rotation of the vibration member 124 in the clockwise direction. However, the first vibration member 122 of the vibration 120 may only be vibrated in a manner similar to that of the driving mode and may not be vibrated in the direction of the Z axis.

The vibration unit 120 may transmit an electrical signal in the second sensing mode. For example, the second vibration member 124 of the vibration unit 120 may transmit the electrical signal while being vibrated in the direction of the Z axis as described above. The electrical signal transmitted from the vibration unit 120 may be sensed by the control unit 140. The control unit 140 may determine magnitudes and directions of angular velocities using magnitudes and deviations of the electrical signal transmitted from the second vibration member 124.

The angular velocity sensor module 100 configured as described above may sense different angular velocities using a single vibration unit 120. Therefore, the angular velocity sensor module 100 according to the present exemplary embodiment may be advantageous for the miniaturization thereof.

Hereinafter, an angular velocity sensor module according to another exemplary embodiment will be described. For reference, the same components to be described hereinbelow as those of the exemplary embodiment in the present inventive concept described above will be denoted by the same reference numerals, and thus, a description of the same components will be omitted.

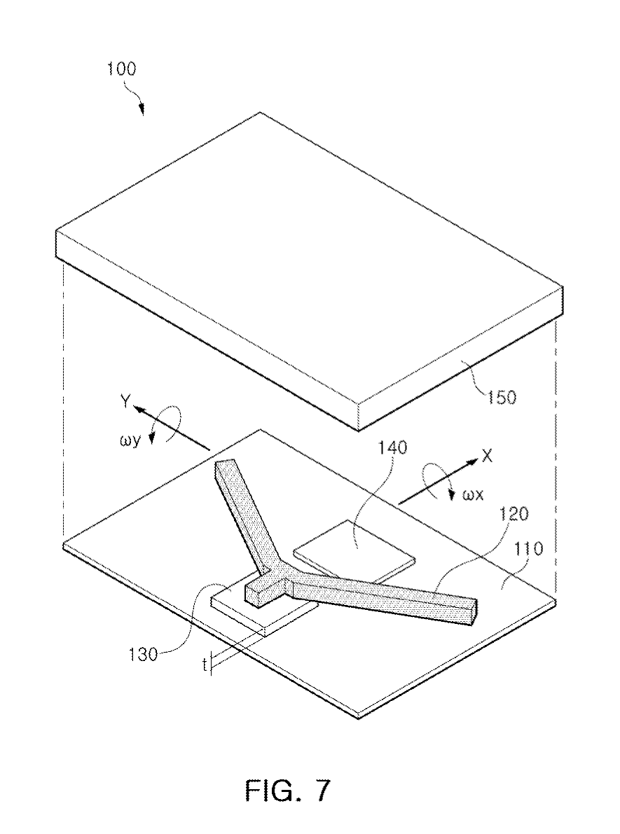

Referring to FIG. 7, an angular velocity sensor module according to another exemplary embodiment will be described.

The angular velocity sensor module 100 according to the present exemplary embodiment may be distinguished from that according to the exemplary embodiment as described above in terms of an arrangement form of a control unit 140. For example, the control unit 140 according to the present exemplary embodiment may be disposed between vibration members of a vibration unit 120. The arrangement form of the control unit 140 may facilitate the miniaturization of the angular velocity sensor module 100.

The angular velocity sensor module 100 according to the present exemplary embodiment may be distinguished from that according to the exemplary embodiment as described above in terms of a form of the vibration unit 120. For example, the vibration unit 120 according to the present exemplary embodiment may be distinguished from that according to the exemplary embodiment as described above in terms of an arrangement form of the vibration members.

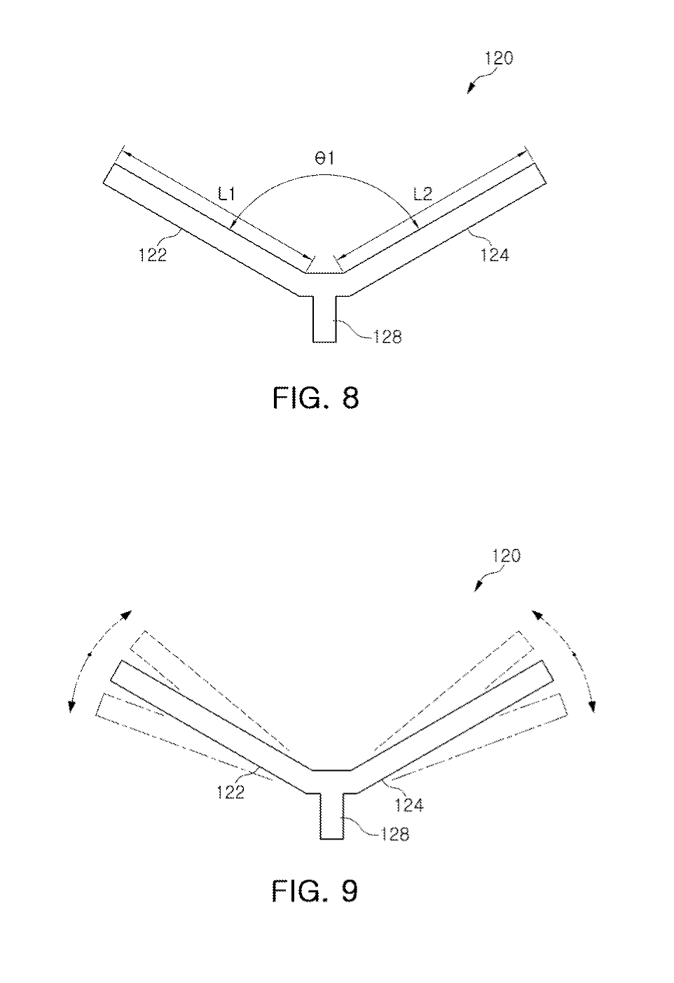

Referring to FIG. 8, the vibration unit will be described.

The vibration unit 120 may include a plurality of vibration members 122 and 124. Further, the vibration unit 120 may include a body member 128. For reference, since the configuration of the body member 128 is the same as or similar to that of the exemplary embodiment as described above, a description of the body member 128 will be omitted.

The vibration members 122 and 124 may be formed on the body member 128. For example, the first vibration member 122 may be formed to be elongated from one side of the body member 128 to one direction of the body member 128, and the second vibration member 124 may be formed to be elongated from one side of the body member 128 to another direction of the body member 128. The first vibration member 122 and the second vibration member 124 may be disposed to form a predetermined angle θ1. For example, a first angle θ1 formed by the first vibration member 122 and the second vibration member 124 based on the body member 128 may be selected from a range of 100 to 170 degrees. However, the size of the first angle θ1 is not limited to the above-mentioned range. For example, the first angle θ1 may be arbitrarily selected from an obtuse angle range or a right angle.

The first vibration member 122 and the second vibration member 124 may have the same shape as each other. For example, a length L1 of the first vibration member 122 and a length L2 of the second vibration member 124 may be the same as each other. The first vibration member 122 and the second vibration member 124 may be symmetrical to each other. For example, the first vibration member 122 and the second vibration member 124 may be disposed to be symmetrical to each other based on the body member 128.

The vibration unit 120 configured as described above may be advantageous for sensing various angular velocities.

The vibration unit 120 may have a plurality of modes. For example, the vibration unit 120 may include a vibration mode, a first sensing mode, and a second sensing mode. Hereinafter, operation modes of the vibration unit 120 based on the respective modes will be described.

Referring to FIG. 9, a driving mode of the vibration unit will be described.

The vibration unit 120 may be operated in the driving mode. For example, the vibration unit 120 may be operated in the driving mode in a state in which angular velocity ωx of the vibration unit 120 in an X axis and angular velocity ωy of the vibration unit 120 in a Y axis are absent.

The driving mode of the vibration unit 120 may be operated so that the first vibration member 122 and the second vibration member 124 are vibrated in a direction parallel with respect to the first plane. For example, the first vibration member 122 may be driven to be rotated in a clockwise direction by a primary driving signal, and may be driven to be rotated in a counterclockwise direction by a secondary driving signal. Similarly, the second vibration member 124 may be driven to be rotated in the counterclockwise direction by the primary driving signal, and may be driven to be rotated in the clockwise direction by the secondary driving signal.

In the driving mode, rotary motion of the vibration members 122 and 124 by the driving signal may only occur. Therefore, transmission of an electrical signal caused by deformation in the vibration members 122 and 124 may not occur in the driving mode.

In a case in which a shaking occurs in the above-mentioned driving mode, the vibration unit 120 may be operated in the first sensing mode or the second sensing mode based on a direction of the shaking.

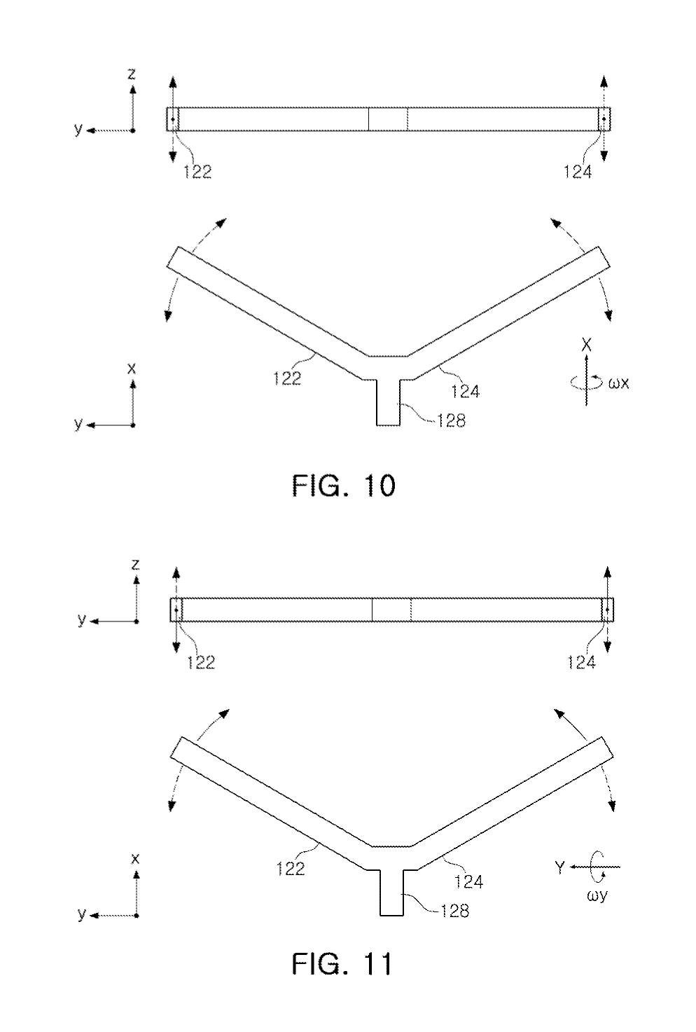

Referring to FIGS. 10 and 11, a sensing mode of the vibration unit will be described.

As an example, in a case in which angular velocity ωx of the X axis is generated, the vibration unit 120 may be operated in the first sensing mode as illustrated in FIG. 10. For example, the first vibration member 122 of the vibration unit 120 may be vibrated in a direction of a +Z axis together with rotation of the first vibration member 122 in the clockwise direction, and may be vibrated in a direction of a −Z axis together with rotation of the first vibration member 122 in the counterclockwise direction. Similarly, the second vibration member 124 of the vibration unit 120 may be vibrated in the direction of the −Z axis together with rotation of the second vibration member 124 in the counterclockwise direction, and may be vibrated in the direction of the +Z axis together with rotation of the second vibration member 124 in the clockwise direction.

As another example, in a case in which the angular velocity ωy of the Y axis is generated in the driving mode, the vibration unit 120 may be operated in the second sensing mode as illustrated in FIG. 11. For example, the first vibration member 122 of the vibration unit 120 may be vibrated in a direction of the +Z axis together with rotation of the first vibration member 122 in the clockwise direction, and may be vibrated in a direction of the −Z axis together with rotation of the first vibration member 122 in the counterclockwise direction. Similarly, the second vibration member 124 of the vibration unit 120 may be vibrated in the direction of the −Z axis together with rotation of the second vibration member 124 in the counterclockwise direction, and may be vibrated in the direction of the +Z axis together with rotation of the second vibration member 124 in the clockwise direction.

The vibration unit 120 may transmit an electrical signal in the sensing mode. For example, the vibration members 122 and 124 of the vibration unit 120 may transmit the electrical signal while being vibrated in the direction of the Z axis as describe above. The electrical signal transmitted from the vibration unit 120 may be sensed by the control unit 140. The control unit 140 may determine magnitudes and directions of angular velocities using magnitudes and deviations of the electrical signal transmitted from the first vibration member 122 and the second vibration member 124.

The angular velocity sensor module 100 configured as described above may sense different angular velocities using a single vibration unit 120. Therefore, the angular velocity sensor module 100 according to the present exemplary embodiment may be advantageous for the miniaturization thereof.

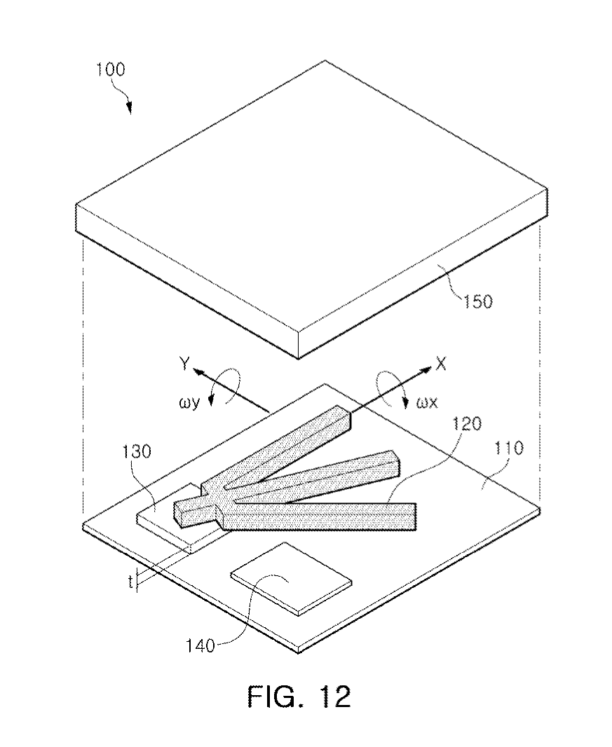

Referring to FIG. 12, an angular velocity sensor module according to another exemplary embodiment will be described.

The angular velocity sensor module 100 according to the present exemplary embodiment may be distinguished from those according to the exemplary embodiments as described above in terms of a form of a vibration unit 120. For example, the vibration unit 120 according to the present exemplary embodiment may include three or more vibration members.

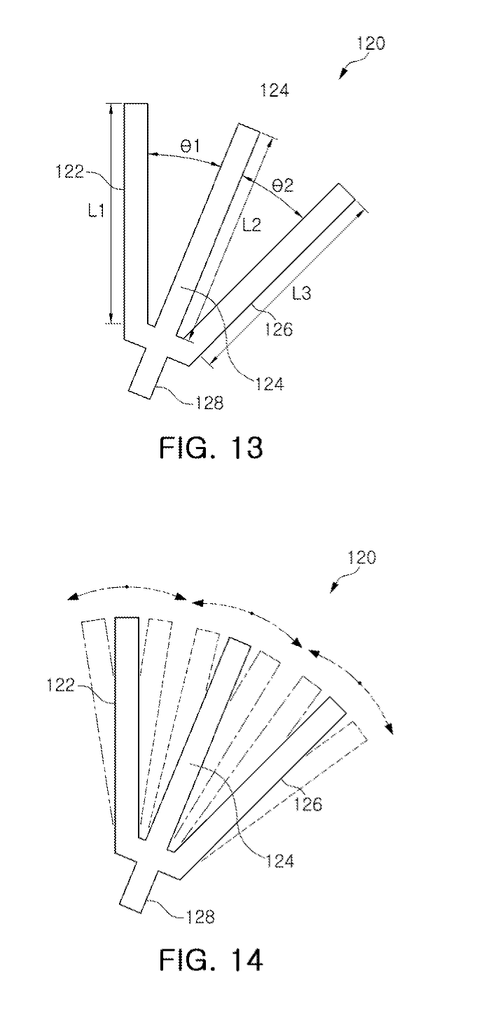

Referring to FIG. 13, the vibration unit will be described.

The vibration unit 120 may include a plurality of vibration members 122, 124, and 126. Further, the vibration unit 120 may include a body member 128. For reference, since the configuration of the body member 128 is the same as or similar to that of the exemplary embodiment as described above, a description of the body member 128 will be omitted.

The vibration members 122, 124, and 126 may be formed on the body member 128. For example, the first vibration member 122 may be formed to be elongated from one side of the body member 128 to one direction of the body member 128, the second vibration member 124 may be formed to be elongated from one side of the body member 128 to another direction of the body member 128, and the third vibration member 126 may be formed to be elongated from one side of the body member 128 to another direction of the body member 128.

The first vibration member 122 and the second vibration member 124 may be disposed to form a predetermined angle θ1. For example, a first angle θ1 formed by the first vibration member 122 and the second vibration member 124 based on the body member 128 may be selected from a range of 10 to 40 degrees. However, the size of the first angle θ1 is not limited to the above-mentioned range. For example, the first angle θ1 may be arbitrarily selected from an acute angle range.

Similarly, the second vibration member 124 and the third vibration member 126 may be disposed to form a predetermined angle θ2. For example, a second angle θ2 formed by the second vibration member 124 and the third vibration member 126 based on the body member 128 may be selected from a range of 10 to 40 degrees. However, the size of the second angle θ2 is not limited to the above-mentioned range. For example, the second angle θ2 may be arbitrarily selected from an acute angle range. As a further example, the second angle θ2 may have the same size as that of the first angle θ1.

The vibration members 122, 124, and 126 may be formed to share the same vibration characteristics as one another. For example, a length L1 of the first vibration member 122, a length L2 of the second vibration member 124, and a length L3 of the third vibration member 126 may be the same as one another. Further, the first vibration member 122 and the third vibration member 126 may be symmetrical to each other based on the second vibration member 124.

The vibration unit 120 configured as described above may sense various angular velocities.

The vibration unit 120 may have a plurality of modes. For example, the vibration unit 120 may include a vibration mode, a first sensing mode, and a second sensing mode. Hereinafter, operation modes of the vibration unit 120 based on the respective modes will be described.

Reference to FIG. 14, a driving mode will be described.

The vibration unit 120 may be operated in the driving mode. For example, the vibration unit 120 may be operated in the driving mode in a state in which angular velocity ωx of an X axis and angular velocity ωy of a Y axis are absent.

The driving mode of the vibration unit 120 may be operated so that the vibration members 122, 124, and 126 are vibrated in a direction parallel with respect to the first plane. For example, the first vibration member 122 and the third vibration member 126 may be driven to be rotated in a clockwise direction by a primary driving signal, and may be driven to be rotated in a counterclockwise direction by a secondary driving signal. Conversely, the second vibration member 124 may be driven to be rotated in the counterclockwise direction by a primary driving signal, and may be driven to be rotated in the clockwise direction by a secondary driving signal.

In the driving mode, rotary motion of the vibration members 122, 124, and 126 by the driving signal may only occur. Therefore, transmission of an electrical signal caused by deformation of the vibration members 122 and 124 may not occur in the driving mode.

However, in a case in which a shaking occurs in the above-mentioned driving mode, the vibration unit 120 may be operated in the sensing mode based on a direction of the shaking.

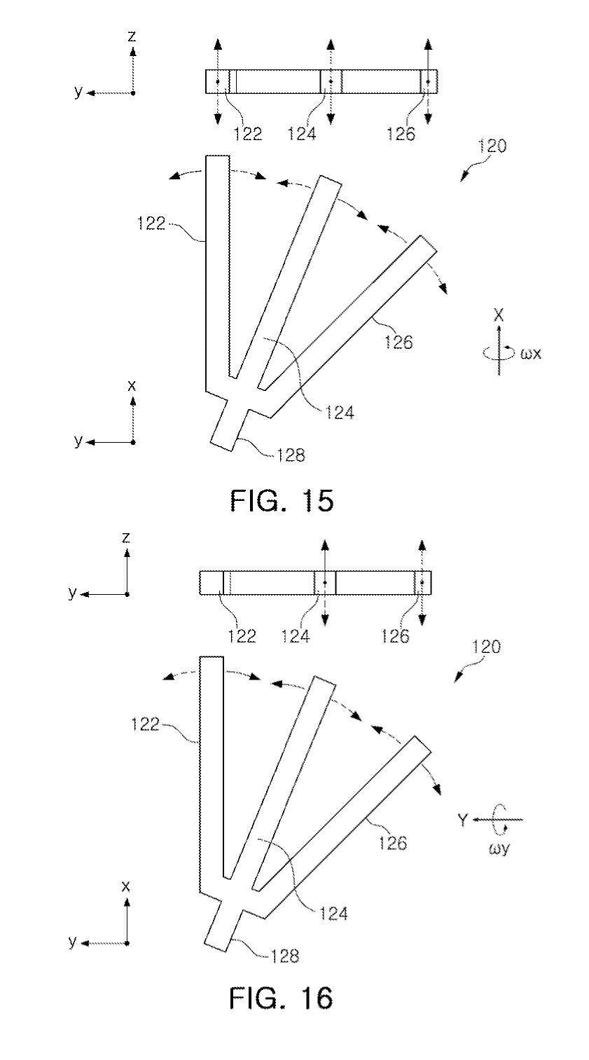

Referring to FIGS. 15 and 16, a sensing mode of the vibration unit will be described.

As an example, in a case in which angular velocity ωx of the X axis is generated, the vibration unit 120 may be operated in the first sensing mode as illustrated in FIG. 15. For example, the vibration members 122, 124, and 126 of the vibration unit 120 may be vibrated in a direction of a +Z axis together with rotation of the vibration members 122, 124, and 126 in the clockwise direction, and may be vibrated in a direction of a −Z axis together with rotation of the vibration members 122, 124, and 126 in the counterclockwise direction.

As a further example, in a case in which angular velocity ωy of the Y axis is generated in the driving mode, the vibration unit 120 may be operated in the second sensing mode as illustrated in FIG. 11. For example, the vibration members 122, 124, and 126 of the vibration unit 120 may be vibrated in the direction of the +Z axis together with rotation of the vibration members 122, 124, and 126 in the clockwise direction, and may be vibrated in the direction of the −Z axis together with rotation of the vibration members 122, 124, and 126 in the counterclockwise direction.

The vibration unit 120 may transmit an electrical signal in the sensing mode. For example, the vibration members 122, 124, and 126 of the vibration unit 120 may all transmit the electrical signal while being vibrated in the direction of the Z axis as described above. The electrical signal transmitted from the vibration unit 120 may be sensed by the control unit 140. The control unit 140 may determine magnitudes and directions of angular velocities using magnitudes and deviations of the electrical signal transmitted from the vibration members 122, 124, and 126.

The angular velocity sensor module 100 configured as described above may sense various angular velocities using a single vibration unit 120. Therefore, the angular velocity sensor module 100 according to the present exemplary embodiment may be advantageous for the miniaturization thereof.

As set forth above, according to exemplary embodiments of the present inventive concept, the angular velocity sensor may be miniaturized.

While exemplary embodiments have been shown and described above, it will be apparent to those skilled in the art that modifications and variations could be made without departing from the scope of the invention as defined by the appended claims.

What is claimed is:

1. A vibration unit, comprising:
a first vibration member configured to be extended from a body member and vibrated on a first plane based on a first driving signal; and
a second vibration member configured to be extended from the body member, disposed to be non-parallel with respect to the first vibration member, and vibrated on the first plane based on a second driving signal.

2. The vibration unit of claim 1, wherein the first vibration member and the second vibration member are disposed to form an acute angle or a right angle, based on the body member.

3. The vibration unit of claim 1, wherein the first vibration member and the second vibration member are disposed to form an obtuse angle or a right angle, based on the body member.

4. The vibration unit of claim 1, wherein the first vibration member and the second vibration member are configured to be vibrated in directions opposing each other, based on the first driving signal and the second driving signal.

5. The vibration unit of claim 1, wherein the vibration members include:
a first piezoelectric element configured to exert driving force by the driving signal; and
a second piezoelectric element configured to convert external vibrations into an electrical signal.

6. The vibration unit of claim 1, further comprising a third vibration member configured to be extended from the body member, disposed to be non-parallel with respect to the first vibration member and the second vibration member, and vibrated on the first plane based on a third driving signal.

7. An angular velocity sensor module, comprising:
a substrate member; and
a vibration unit configured to be formed on the substrate member, vibrated based on a driving signal, and converting external vibrations into an electrical signal,
wherein the vibration unit includes:
a body member fixed to the substrate member;
a first vibration member extended from the body member; and
a second vibration member extended from the body member and disposed to be non-parallel with respect to the first vibration member.

8. The angular velocity sensor module of claim 7, further comprising a pedestal member disposed between the substrate member and the vibration unit to maintain the vibration unit to be spaced apart from the substrate member by a first height.

9. The angular velocity sensor module of claim 7, wherein the first vibration member and the second vibration member are disposed to form an acute angle based on the body member.

10. The angular velocity sensor module of claim 7, wherein the first vibration member and the second vibration member are disposed to form an obtuse angle based on the body member.

11. The angular velocity sensor module of claim 7, further comprising a control unit configured to transmit a driving signal to the vibration unit and convert the electrical signal of the vibration unit.

12. The angular velocity sensor module of claim 11, wherein the control unit is disposed between the first vibration member and the second vibration member.

13. The angular velocity sensor module of claim 7, wherein the first vibration member and the second vibration member are configured to be vibrated in directions opposing each other based on the driving signal.

14. The angular velocity sensor module of claim 7, wherein the vibration unit further includes a third vibration member configured to be extended from the body member, disposed to be non-parallel with respect to the first vibration member and the second vibration member, and vibrated based on the driving signal.

15. The angular velocity sensor module of claim 14, wherein the third vibration member is configured to be vibrated in a direction the same as a direction in which the first vibration member is vibrated based on the driving signal.
